(19) United States
(12) Patent Application Publication
(10) Pub. No.: US 2013/0248809 A1
(43) Pub. Date: Sep. 26, 2013

(54) VARIABLE RESISTIVE ELEMENT AND NONVOLATILE SEMICONDUCTOR MEMORY DEVICE

(71) Applicants: SHARP KABUSHIKI KAISHA, Osaka (JP); ELPIDA MEMORY, INC., Tokyo (JP)

(72) Inventors: Yukio TAMAI, Osaka (JP); Takashi NAKANO, Osaka (JP); Nobuyoshi AWAYA, Osaka (JP); Kazuo AIZAWA, Tokyo (JP); Isamu ASANO, Tokyo (JP); Naoya HIGANO, Tokyo (JP); Tsuyoshi KAWAGOE, Tokyo (JP)

(73) Assignees: ELPIDA MEMORY, INC., Tokyo (JP); SHARP KABUSHIKI KAISHA, Osaka (JP)

(21) Appl. No.: 13/848,926

(22) Filed: Mar. 22, 2013

(30) Foreign Application Priority Data
Mar. 22, 2012 (JP) 2012-065820

(51) Int. Cl. H01L 45/00

(52) U.S. Cl. CPC H01L 45/126
USPC 257/4

(57) ABSTRACT

As for a variable resistive element including first and second electrodes, and a variable resistor containing a metal oxide between the first and second electrodes, in a case where a current path having a locally high current density of a current flowing between the both electrodes is formed in the metal oxide, and resistivity of at least one specific electrode having higher resistivity of the both electrodes is 100 μΩcm or more, a dimension of a contact region of the specific electrode with the variable resistor in a short side or short axis direction is set to be more than 1.4 times as long as a film thickness of the specific electrode, which reduces variation in parasitic resistance generated in an electrode part due to process variation of the electrode, and prevents variation in resistance change characteristics of the variable resistive element generated due to the variation in parasitic resistance.

### CROSS REFERENCE TO RELATED APPLICATION

This Nonprovisional application claims priority under 35 U.S.C. §119(a) on Patent Application No. 2012-065820 filed in Japan on Mar. 22, 2012 the entire contents of which are hereby incorporated by reference.

### BACKGROUND OF THE INVENTION

1. Field of the Invention

The present invention relates to a nonvolatile variable resistive element including a first electrode, a second electrode, and a layer serving as a variable resistor formed of a metal oxide and sandwiched between the above electrodes, and a nonvolatile semiconductor memory device using the variable resistive element for storing information.

2. Description of the Related Art

Recently, as a high-speed operable next-generation nonvolatile random access memory (NVRAM) to replace a flash memory, various device structures such as FeRAM (Ferroelectric RAM), MRAM (Magnetic RAM), and PRAM (Phase Change RAM) have been proposed, and they face intense development competition with a view to improving performance, increasing reliability, lowering cost, and ensuring consistency with processes.

With respect to these existing techniques, RRAM (Resistive Random Access Memory) which is a nonvolatile resistive memory using a variable resistive element whose electric resistance is changed reversibly by applying a voltage pulse has been proposed. FIG. 14 shows this configuration.

As shown in FIG. 14, a conventional variable resistive element has a structure in which a lower electrode 103, a variable resistor 102, and an upper electrode 101 are laminated in this order, and it is characterized in that when a voltage pulse is applied between the upper electrode 101 and the lower electrode 103, its resistance value can be reversibly changed. A new nonvolatile semiconductor memory device can be realized by reading a resistance value which is changed by this reversible resistance changing action (hereinafter, referred to as the “switching action”).

The nonvolatile semiconductor memory device is composed by forming a memory cell array in which memory cells each including a variable resistive element are arranged in a shape of matrix in a row direction and a column direction, and by arranging periphery circuits to control programming, erasing, and reading actions of data for each memory cell of the memory cell array. Thus, the memory cell is classified according to a difference in component, and there are a memory cell which includes one selection transistor T and one variable resistive element R (referred to as the “1T1R type”) and a memory cell which only includes one variable resistive element R (referred to as the “1R type”), and the like. Among them, FIG. 12 shows a configuration example of the 1T1R type memory cell.

FIG. 12 is an equivalent circuit diagram showing one configuration example of the memory cell array having the 1T1R type memory cells. A gate of the selection transistor T in each memory cell is connected to a word line (WL1 to WLn), and a source of the selection transistor T in each memory cell is connected to a source line (SL1 to SLn) (n is a natural number). In addition, one electrode of the variable resistive element R in each memory cell is connected to a drain of the selection transistor T, and the other electrode of the variable resistive element R is connected to the bit line (BL1 to BLm) (m is a natural number). In addition, the word lines WL1 to WLn are connected to a word line decoder 24, and the source lines SL1 to SLn are connected to a source line decoder 26, and the bit lines BL1 to BLm are connected to a bit line decoder 25. Thus, in response to an address input (not shown), the specific bit line, word line, and source line are selected for programming, erasing, and reading actions for the specific memory cell C in a memory cell array 21.

Thus, according to the configuration in which the selection transistor T and the variable resistive element R are arranged in series, the transistor of the memory cell selected by a potential change of the word line is turned on, and programming or erasing can be selectively performed only for the variable resistive element R of the memory cell selected by a potential change of the bit line.

As for the above variable resistive element R, a method for reversibly changing electric resistance by applying a voltage pulse to a perovskite material known for a supergiant magnetoresistance effect, which is a variable resistance material used for a variable resistor, is disclosed in U.S. Pat. No. 6,204,139 (hereinafter, referred to as a “well-known document 1”) by Shangquing Liu or Alex Ignatiev at Houston University in the United States, and in “Bistable Switching in Electroformed Metal-Insulator-Metal Devices”, Phys. Stat. Sol. (a), Vol. 108, pp. 11-65, in 1988 (hereinafter, referred to as a “well-known document 2”) by H. Pagnia et al. By this method, the several-digit resistance change appears in room temperature without applying a magnetic field even when the perovskite material known for the supergiant magnetoresistance effect is used. In addition, according to an element structure illustrated in the well-known document 1, as the material of the variable resistor, praseodymium calcium manganese oxide Pr₁₋ₓCaₓMnO₃ (PCMO) film which is a perovskite type oxide is used.

In addition, as another variable resistor material, an oxide of a transition metal element such as a titanium oxide (TiO₂) film, nickel oxide (NiO) film, zinc oxide (ZnO) film, or niobium oxide (Nb₂O₅) film shows the reversible resistance change as shown in the well-known document 2 and “Highly Scalable Non-volatile Resistive Memory using Simple Binary Oxide Driven by Asymmetric Unipolar Voltage Pulses”, IEDM 2004, pp. 587-590, in 2004 by Baek, I. G. et al.

In addition, the fact that the variable resistive element includes a type in which a resistance change occurs over a whole interface of the electrode and the variable resistor, and a type in which a resistance change occurs when a filament in which a current locally flows in the variable resistor is formed or broken (filament type) is disclosed by A. Sawa, “Resistive switching in transition metal oxides”, Materials Today, Vol. 11, pp. 28-36, in 2008.

In order to provide a highly integrated memory of Gbit class with the variable resistive element, it is necessary that an element having a fine size of the order of several 10 nm is uniformly operated at low voltage. In order to attain it, variation in parasitic resistance of the element part has to be as small as possible, and a parasitic resistance value itself has to be reduced. In addition, the variation in parasitic resistance is generated due to fluctuation in dimension of the electrode mainly caused by a process variation in a manufacturing process.

However, it is not clear how the parasitic resistance is controlled in the miniaturized filament type variable resistive element, and there is no guideline for a method for reducing the parasitic resistance at the present.

By the way, when the variable resistive element is applied to the highly integrated memory, it is preferably to be formed of material which can be easily used in the manufacturing process. On the other hand, as for the variable resistive element having the metal oxide as the variable resistor, it is known that there is selectivity between a material of the variable resistor and a material of the electrode with which the resistance switching can be stably performed. That is, it is known that a kind of the electrode material which can be used for the electrode of the variable resistive element is limited, according to the variable resistor material. Thus, the material which can be easily used in the manufacturing process is not always employed as the electrode material.

The variable resistive element having the metal oxide as the variable resistor uses the electrode formed of noble metal such as Pt, Ru, or Ir in many cases, but the problem is that it is hard to perform the miniaturizing process to provide the highly integrated memory with this kind of material, or the material itself is expensive.

On the other hand, while taking account of a constraint condition of the available combination of the electrode material and the variable resistor material, the material which can satisfy the above constraint condition and be easily used in the manufacturing process can be selected as the electrode material. However, due to the constraint condition, the material having relatively high resistivity has to be employed as the electrode material in some cases. When the material having high resistivity is used as the electrode material, the above-described parasitic resistance and the variation in parasitic resistance caused in the variable resistive element are increased as a matter of course, which causes the problem in providing the highly integrated memory.

Especially, when the resistivity of the electrode material is 100 μΩcm or more, the problem of the parasitic resistance value and the variation in parasitic resistance becomes serious, so that it is difficult to provide the highly integrated memory.

### SUMMARY OF THE INVENTION

In view of the above problems, it is an object of the present invention to provide a variable resistive element as a filament type variable resistive element having a structure capable of reducing a parasitic resistance value of the variable resistive element, and reducing variation in parasitic resistance generated due to fluctuation in electrode dimension.

In addition, it is another object of the present invention to provide a highly integrated nonvolatile memory provided with the above variable resistive element in which the parasitic resistance value and the variation in parasitic resistance are reduced.

A variable resistive element according to the present invention to attain the above object, is characterized by including a first electrode, a second electrode, and a variable resistor containing a metal oxide, the variable resistor being provided between the first and second electrodes, wherein

electric resistance between the first and second electrodes is reversibly changed in response to application of an electric stress to between the first and second electrodes,

the metal oxide includes a current path where a current density of a current flowing between the first and second electrodes is locally high,

resistivity of at least one specific electrode having higher resistivity of the first electrode and the second electrode is 100 μΩcm or more, and

a dimension of a contact region of the specific electrode with the variable resistor in a short side direction or a short axis direction is more than 1.4 times as long as a film thickness of the specific electrode.

The variable resistive element according to the present invention having the above characteristic is preferably configured such that the specific electrode is formed to have a dimension larger than the variable resistor in the short side direction or the short axis direction, and

the specific electrode extends from a boundary of the contact region to an outer region by more than 0.7 times as long as the film thickness of the specific electrode.

Further, the variable resistive element according to the present invention having the above characteristic is preferably configured such that the specific electrode is formed of a material containing nitrogen, an oxide material, or a silicon material doped with an impurity.

Further, the variable resistive element according to the present invention having the above characteristic is preferably configured such that the dimension of the contact region in the short side direction or the short axis direction is 50 nm or less.

A semiconductor device according to the present invention to attain the above object, is characterized by including:

a semiconductor substrate; and

a plurality of memory cells over the semiconductor substrate, each of the memory cells including a variable resistive element that includes:

a first conductive layer;

a second conductive layer greater in resistivity than the first conductive layer, a resistivity of the second conductive layer being equal to or more than 100 μΩcm, and a thickness of the second conductive layer is a first value; and

a variable resistive film sandwiched between the first and second conductive layer to define a contact region between the variable resistive film and the second conductive layer, a shape of the contact region being substantially a circle shape of which diameter is equal to or more than 1.4 times as the first value.

The semiconductor device according to the present invention having the above characteristic is preferably configured such that the second conductive layer includes a first surface, the variable resistive film including a second surface connecting to the first surface to define the contact region, the first surface being larger than the second surface.

The semiconductor device according to the present invention having the above characteristic is preferably configured such that the second conductive layer is formed of at least one of a material containing nitrogen, an oxide material, and a silicon material doped with an impurity.

The semiconductor device according to the present invention having the above characteristic is preferably configured such that the diameter of the circle shape of the contact region is equal to or less than 50 nm.

A semiconductor device according to the present invention to attain the above object, is characterized by including:

a semiconductor substrate; and

a plurality of memory cells over the semiconductor substrate, each of the memory cells including a variable resistive element that includes:

a first conductive layer;

a second conductive layer greater in resistivity than the first conductive layer, a resistivity of the second conductive layer being equal to or more than 100 μΩcm, and a thickness of the second conductive layer is a first value; and

a variable resistive film sandwiched between the first and second conductive layer to define a contact region between the variable resistive film and the second conductive layer, a shape of the contact region being substantially an ellipse shape of which a minor axis is equal to or more than 1.4 times as the first value.

The semiconductor device according to the present invention having the above characteristic is preferably configured such that the second conductive layer includes a first surface, the variable resistive film including a second surface connecting to the first surface to define the contact region, the first surface being larger than the second surface.

The semiconductor device according to the present invention having the above characteristic is preferably configured such that the second conductive layer is formed of at least one of a material containing nitrogen, an oxide material, and a silicon material doped with an impurity.

The semiconductor device according to the present invention having the above characteristic is preferably configured such that the diameter of the circle shape of the contact region is equal to or less than 50 nm.

The inventors of the present invention have focused on a current flow from a contact point between the filament and the electrode to the electrode, or from the electrode to the contact point in the filament type variable resistive element, and found a guideline for reducing the variation in parasitic resistance caused by the variation in electrode dimension in the fine element, as a result of their earnest study.

Thus, as for the nonvolatile semiconductor memory device provided with fine variable resistive elements, the variation in parasitic resistance due to process variation of the electrode can be reduced, and it becomes possible to provide a highly integrated memory in which variation in resistance change characteristics (switching characteristics) is reduced and an operation margin is large.

### BRIEF DESCRIPTION OF THE DRAWINGS

FIG. 1 is a schematic sectional view illustrating one example of a structure of a variable resistive element according to one embodiment of the present invention;

FIG. 2 is a view showing behavior of a current flowing in an electrode of a filament type variable resistive element;

FIG. 3 is a view for describing behavior of electric field distribution generated when the current flows in the electrode of the filament type variable resistive element;

FIG. 4 is a view showing a relationship between a current density distribution and a current amount of the current flowing in the electrode through a filament;

FIGS. 5A and 5B show an experiment result for evaluating an effect of parasitic resistance caused in the electrode in switching characteristics of the variable resistive element by changing resistivity of an electrode material;

FIG. 6 show an experiment result for evaluating an effect of parasitic resistance caused in the electrode in switching characteristics of the variable resistive element by changing electrode dimensions;

FIG. 7 is a view showing fluctuation in current flowing in the electrode with respect to dimensional variation of the electrode; and

FIGS. 8A and 8B are views each showing behavior of a current flowing in the electrode of the filament type variable resistive element, depending on a position of a formed filament.

FIG. 9 is a schematic sectional view illustrating one example of a structure of a variable resistive element according to one embodiment of the present invention;

FIG. 10 is a schematic sectional view illustrating another example of a structure of a variable resistive element according to one embodiment of the present invention;

FIG. 11 is a circuit block diagram illustrating a schematic configuration of a non-volatile semiconductor memory device according to the present invention;

FIG. 12 is a circuit diagram illustrating a schematic configuration of a memory cell array having 1T1R structure including a variable resistive element;

FIG. 13 is a schematic sectional view illustrating one example of a structure of a memory cell array including the variable resistive element according to the present invention;

FIG. 14 is a schematic sectional view illustrating one example of a structure of a conventional variable resistive element.

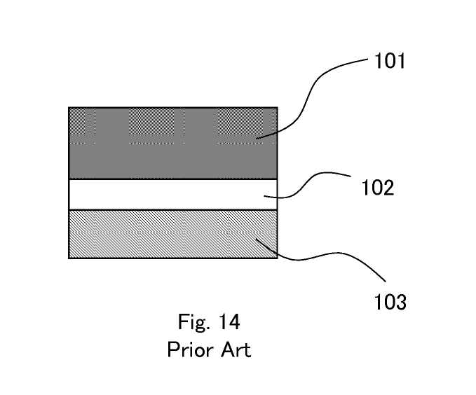

FIG. 15 shows a definition of R.

### DESCRIPTION OF THE PREFERRED EMBODIMENTS

### First Embodiment

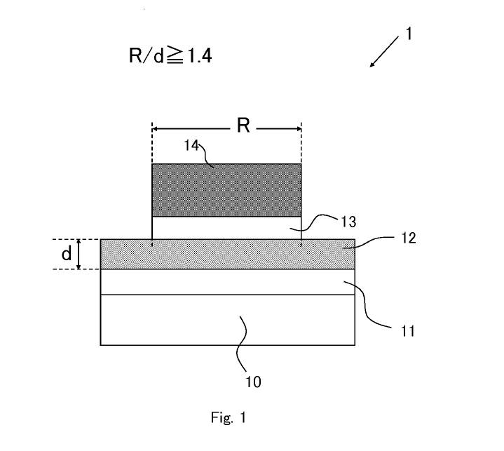

FIG. 1 is a sectional view schematically illustrating a structure of a variable resistive element 1 (hereinafter appropriately referred to as a “present element 1”) according to one embodiment of the present invention. In the drawings described below, essential parts are emphasized for the sake of convenience of description, and a dimensional ratio of each component of the element and an actual dimensional ratio do not agree with each other in some cases.

The variable resistive element 1 includes a second electrode (lower electrode) 12, a variable resistor 13, and a first electrode (upper electrode) 14, those of which are deposited and patterned in this order on an insulating film 11 formed on a substrate 10. The variable resistor 13 includes a layer which is made of a metal oxide or a metal oxynitride.

In the present embodiment, hafnium oxide (HfO_{X}) that has a large bandgap and that is an insulating layer is selected to be used for the metal oxide serving as a variable resistor 13. However, the present invention is not limited thereto. Examples of the variable resistor 13 include metal oxides or oxynitrides, such as zirconium oxide (ZrO_{X}), titanium oxide (TiO_{X}), tantalum oxide (TaO_{X}), tungsten oxide (WO_{X}), aluminum oxide (AlO_{X}), germanium oxide (GeO_{X}), hafnium oxynitride (HfO_{X}N_{Z}), zirconium oxynitride (ZrO_{X}N_{Z}), titanium oxynitride (TiO_{X}N_{Z}), tantalum oxynitride (TaO_{X}N_{Z}), tungsten oxynitride (WO_{X}N_{Z}), aluminum oxynitride (AlO_{X}N_{Z}), or germanium oxynitride (GeO_{X}N_{Z}). These show an n-type conductive property.

When any of the above described metal oxides or oxynitrides is used for the variable resistor 13 to form a variable resistive element, in order to allow the variable resistive element, which is in the initial state just after being produced, to have a state (variable resistance state) in which the resistance state can be changed between a high resistance state and a low resistance state by electric stress, it is necessary to perform a so-called forming process before the variable resistive element is used. Specifically, in the forming process, a voltage pulse, which has a larger voltage amplitude and a longer pulse width compared to those of a voltage pulse used for a normal writing action, is applied to the variable resistive element so as to form a current path where resistance switching occurs in the variable resistor 13. Thus, a conductive path (filament) is formed such that a current density of a current flowing in the variable resistor 13 locally becomes high.

Thus, it is known that the filament formed by the above forming process determines subsequent electric characteristics of the element. The filament path is considered to be formed or to disappear because oxygen atom is collected or diffused by an electric field near an interface between the electrode and the variable resistor. With this phenomenon, the resistance change is considered to be caused.

It is also considered that the resistance change occurs on the interface between the metal oxide or oxynitride and the electrode having a larger potential barrier and a larger work function. Therefore, according to the present element 1, one of the first electrode 14 and the second electrode 12 is formed of conductive material having a larger work function and connected to the variable resistor 13 with the schottky junction, and the other is formed of conductive material having a smaller work function and connected to the variable resistor 13 with the ohmic junction. In this configuration, it is known that the variable resistive element shows the stable resistance switching.

When the work function of the second electrode 12 is larger than the work function of the first electrode 14, it is preferable that the material of the first electrode 14 is selected from conductive materials having a work function smaller than 4.5 eV, while the material of the second electrode 12 is selected from conductive materials having a work function equal to or larger than 4.5 eV. Examples of the conductive material forming the first electrode 14 include Ti (4.1 eV), Hf (3.9 eV), and Zr (4.1 eV) in addition to Ta described above (the value in each parenthesis indicates a work function of the corresponding metal). Similarly, examples of the conductive material forming the second electrode 12 include Ti oxynitride (TiO_{X}N_{Z}), Ta nitride (TaN_{Z}), Ta oxynitride (TaO_{X}N_{Z}), titanium aluminum nitride (TiAlN), W, WN_{X}, Ru, RuO_{X}, Ir, IrO_{X}, or ITO (Indium Tin Oxide) in addition to Pt and TiN described above. Among the electrode materials, the combination of Ti or Ta for the first electrode 14 and TiN for the second electrode 12 is preferable from the viewpoint of easiness in integration processing.

However, when the second electrode 12 is formed of TiN, parasitic resistance of the electrode part in the variable resistive element is high because electric resistance of TiN is relatively high, which hinders effort to provide a highly integrated nonvolatile memory.

In addition, as for an electrode formed of material containing nitrogen such as TiON, or TaN, an electrode formed of oxide such as iridium oxide, and an electrode formed of silicon doped with impurity, their resistivity is 100 μΩcm or more in general, and this value is more than ten times as high as that of a general metal. When the electrode of the variable resistive element is formed of the above electrode material, the parasitic resistance value and variation in parasitic resistance are naturally great in the electrode part of the variable resistive element, so that it is difficult to provide the highly integrated nonvolatile memory in general.

However, according to the element 1 of the present invention, as for the specific electrode (second electrode 12) having the higher resistivity, its dimension R in a short side direction or a short axis direction in a contact region with the variable resistor 13 is set to be more than 1.4 times (Rid 1.4) as long as a film thickness d of the specific electrode, which solves the problem of the parasitic resistance in the electrode part of the variable resistive element. Hereinafter, this will be described in detail.

<<Current Distribution and Parasitic Resistance in Electrode of Filament Type Variable Resistive Element>>

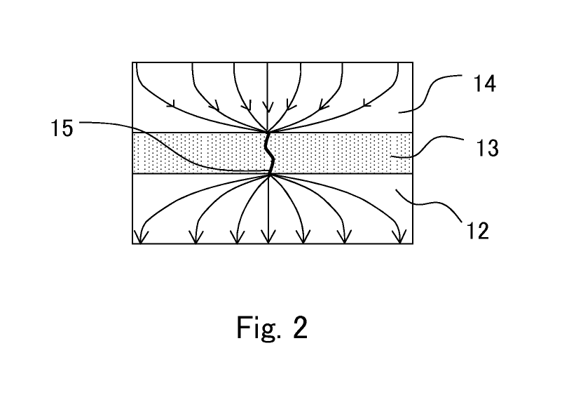

As for the filament type variable resistive element, as described above, it is necessary to perform the initializing operation called the forming process to form the filament-shaped current path in the variable resistor 13. When this current path is broken or re-formed by the application of the electric stress, the electric resistance of the element is changed to the high resistance state or the low resistance state. FIG. 2 schematically shows behavior of a current which spreads from a fine contact point between the filament and the electrode, in the low resistance state. The current radially flows out of or into the contact point between the filament 15 in the variable resistor 13 and the electrode 12. This spread of the current is to be studied to know how to configure the electrode shape.

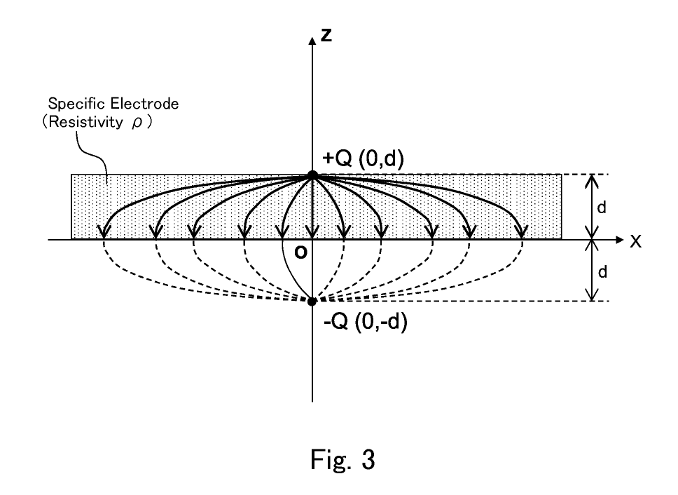

An electric field directed from the fine contact point to the specific electrode is to be considered. As shown in FIG. 3, it is assumed that a film thickness of the specific electrode is d, and a position of the fine contact point between the filament and the specific electrode lies in coordinates (0, d). An ideal circumstance is assumed such that a potential is equal in an end boundary of the specific electrode which is not in contact with the filament, that is, an XY plane (Z=0) is an equipotential plane. Under this boundary condition, the electric field generated in the specific electrode is a sum of an electric field induced by a point charge +Q arranged in the fine contact point (0, d) between the filament and the specific electrode, and an electric field induced by a mirror-image charge −Q arranged in coordinates (0, −d). In the boundary of the specific electrode opposite to the side of the filament (Z=0), the electric field only includes a component Ez in a Z direction, and this is expressed by a following formula 1, where x represents a distance from the fine contact point. Here, it is to be noted that −Z direction in FIG. 3 is a positive direction of the electric field, and ∈ represents a dielectric constant of the specific electrode.

$${E}_{Z} ( x ) = \frac{+ Q}{4 πɛ ( {d}^{2} + {x}^{2} )} \frac{d}{\sqrt{{d}^{2} + {x}^{2}}} - \frac{- Q}{4 πɛ ( {d}^{2} + {x}^{2} )} \frac{d}{\sqrt{{d}^{2} + {x}^{2}}} = \frac{Q}{2 πɛ ( {d}^{2} + {x}^{2} )} \frac{d}{\sqrt{{d}^{2} + {x}^{2}}} \qquad ( 1 )$$

Therefore, a current density in a region Z=0 is expressed by a following formula 2, where ρ represents resistivity of the specific electrode.

$$J ( x ) = {E}_{Z} ( x ) / ρ = {\frac{Q}{2 πɛρ {d}^{2}} [ 1 + {( \frac{x}{d} )}^{2} ]}^{- \frac{3}{2}} \qquad ( 2 )$$

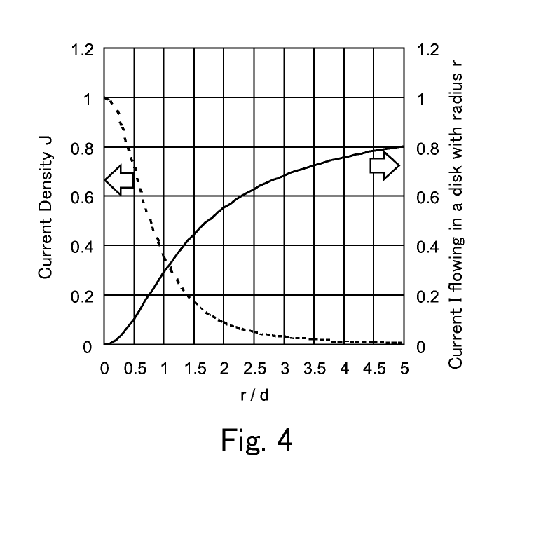

FIG. 4 shows a distribution of a current density J(r), with a dotted line, normalized on the assumption that the current density is 1 when r=0, where d represents the film thickness of the specific electrode, and r represents the distance from the fine contact point. In a case where the specific electrode is a disk having a radius of r and a thickness of d and provided around the fine contact point, a current I flowing in the specific electrode is obtained by integrating the current density with respect to x from 0 to r, and expressed by a following formula 3.

$$I ( r / d ) = {\int }_{0}^{r} J ( x ) \cdot 2 π x d x = \frac{Q}{ɛρ} [ 1 - {( 1 + {( \frac{r}{d} )}^{2} )}^{- \frac{1}{2}} ] \qquad ( 3 )$$

Based on the formula 3, behavior of the current I flowing in the specific electrode is expressed by a formula 4.

I˜(Q/2∈ρd²)·r², where r/d˜0

I˜Q/∈ρ, where r/d>>1 (4)

A change of the current I flowing in the disk-shaped specific electrode having the radius of r with respect to r/d is shown by a solid line in FIG. 4. In addition, FIG. 4 shows the current I normalized on the assumption that its value is 1 when r→∞. As can be seen from FIG. 4, the current density J is maximum in the fine contact point, and the current density is reduced with distance from the fine contact point. A size of the electrode in an actual device is limited, and as the electrode size is reduced, the current due to the current density J in the region in which r/d is great in FIG. 4 does not flow, so that the total current amount I is reduced. This result appears as the increase in parasitic resistance caused in the specific electrode.

Furthermore, FIG. 4 shows that when an element area is large, the variation in parasitic resistance in the specific electrode is small even when the variation in element area is generated, but when the element area is small, the parasitic resistance caused in the specific electrode becomes sensitive with respect to the variation in electrode area.

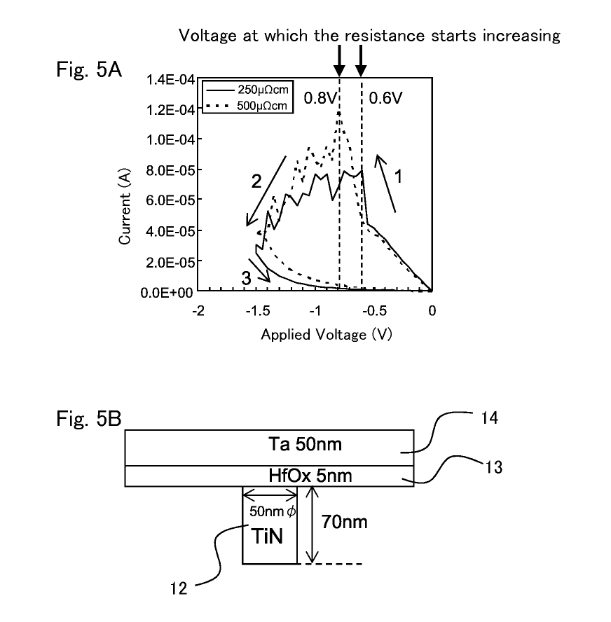

FIGS. 5A and 5B show a result of an experiment performed to show that the parasitic resistance in the specific electrode affects an operating voltage of the variable resistive element. FIG. 5A shows IV characteristics in a variable resistive element having a structure of Ta/HfOₓ/TiN in the case where the variable resistive element is changed to the high resistance state. A dimension and a film thickness of the variable resistive element are provided as shown in FIG. 5B, and the element has a contact area of 50 nmφ between the variable resistor (HfOₓ) 13 and the second electrode (TiN) 12. A solid line in FIG. 5A shows IV characteristics of the element having the TiN electrode, which is formed by atomic layer deposition (ALD) and has resistivity of 250 μΩcm, in the case where the element is changed to the high resistance state, and a dotted line in FIG. 5A shows IV characteristics of the element having the TiN electrode, which is formed by chemical vapor deposition (CVD) and has resistivity of 500 μΩcm, in the case where the element is changed to the high resistance state. As can be seen from FIG. 5A, the voltage at which the resistance starts increasing is higher in the case where the resistivity of the TiN electrode is higher, and the parasitic resistance in the electrode affects the switching characteristics of the variable resistive element. This is because when the resistivity of the specific electrode is high, a voltage drop generated in the specific electrode is increased, so that it is necessary to apply a higher voltage to the variable resistive element.

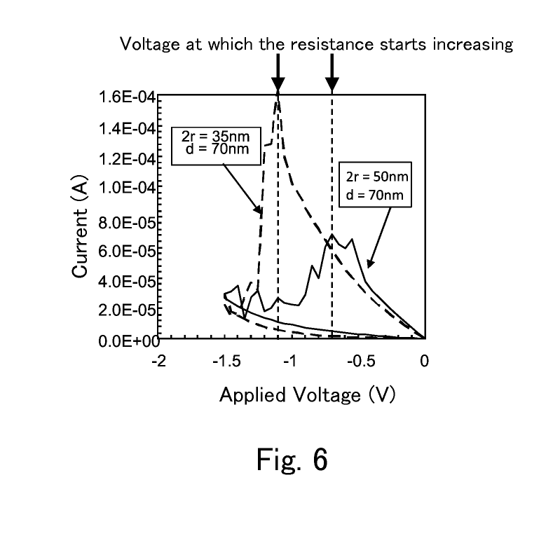

In addition, FIG. 6 shows IV characteristics of elements having different electrode dimensions (2r=50 nmφ and 35 nmφ) in the case where the elements are changed to the high resistance state. Configuration of the variable resistive element is the same as that shown in FIG. 5B except for the electrode dimension. It can be seen from FIG. 6 that the voltages at which the resistance starts increasing are different from each other, depending on the electrode dimension. Therefore, when the variation in electrode dimension is generated in a manufacturing process, the variation in parasitic resistance is generated in the electrode, which causes variation in voltage at which the resistance starts increasing, the voltage serving as the switching characteristics of the variable resistive element. Thus, it is difficult to provide the highly integrated memory in which variation in switching characteristics is prevented and the operation margin is large, by use of the element having the specific electrode which is mounted with a fine dimension and has resistivity of 100 μΩcm or more.

<<Method for Reducing Variation in Parasitic Resistance According to the Present Invention>>

Hereinafter, a detailed description will be given of a method for reducing an effect due to the variation in parasitic resistance, while taking account of the variation in dimension of the specific electrode.

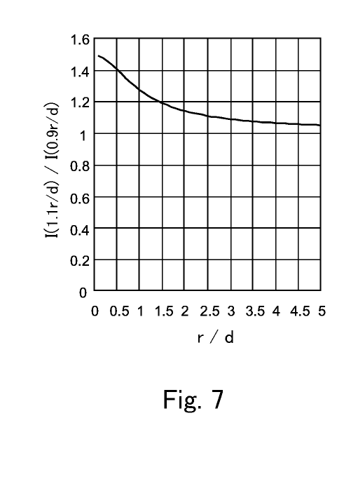

FIG. 7 shows a ratio of a current I flowing in a disk-shaped specific electrode having a radius of 1.1 r, and a current I flowing in a disk-shaped specific electrode having a radius of 0.9 r, as a function of r/d, based on FIG. 4 while a film thickness d of the specific electrode is the same. That is, FIG. 7 shows variation in current flowing in the specific electrode when the electrode dimension varies by ±10% from r.

FIG. 7 shows that a fluctuation range of the parasitic resistance in the specific electrode due to the fluctuation in electrode dimension is increased as r/d is reduced. Meanwhile, in a case where the current flows in the electrode at uniform current density, when the dimension variation is ±10%, the resistance change is about 1.5(=(1.1/0.9)²), and it is constant without regard to the electrode radius r or the film thickness d.

Here, referring to the formula 4, the current I flowing in the specific electrode is proportional to r², that is, the electrode area at the limit where r/d is very small (r/d˜0). Therefore, the fluctuation range of the parasitic resistance in the specific electrode due to the fluctuation in electrode dimension is equal to that in the case where the current flows in the electrode at the uniform current density at the limit where r/d is very small (r/d˜0).

Meanwhile, referring to the formula 4, the current I flowing in the specific electrode is converged to a constant value at the limit where r/d is great (r/d>>1). Therefore, as r/d is increased, a fluctuation ratio of the parasitic resistance in the specific electrode due to the fluctuation in electrode dimension comes close to 1, and the variation in parasitic resistance is reduced. As can be known from the above description, this is the specific feature of the filament type variable resistive element.

Next, consideration will be given to a condition capable of efficiently preventing the variation in parasitic resistance, by use of dependency of the parasitic resistance on the electrode dimension. When the fluctuation in electrode dimension is ±10% in the case where the current flows uniformly in the electrode, the fluctuation ratio of the parasitic resistance is (1.1/0.9)²)=1.5, so that in order to improve this by 10% or more, the fluctuation ratio has to be set at 1.35 or less. The condition to satisfy this is r/d 0.7 as can be seen from FIG. 7. When a diameter of the specific electrode is R (=2r), the condition R/d≧1.4 is to be satisfied. For example, in the case of the element having the TiN electrode whose dimension is 50 nmφ shown in FIGS. 5A and 6, the film thickness d of the TiN electrode is set to the condition d 36 nm.

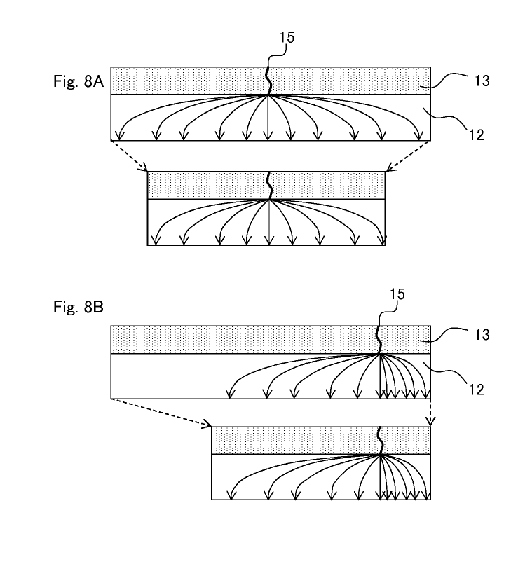

In addition, in the above description, the relational expression between the dimension and the film thickness of the specific electrode is derived on the assumption that the filament is formed in the center of the contact region between the electrode and the variable resistor. In fact, the filament is formed in an inner peripheral part other than the center part of the contact region between the electrode and the variable resistor. However, the filament provided in the vicinity of the center of the electrode is most susceptible to the effect of the fluctuation in parasitic resistance due to the fluctuation in electrode dimension. As shown in FIG. 8A, a current flowing from the filament provided in the vicinity of the center of the electrode flows uniformly to the electrode end, so that the fluctuation in parasitic resistance due to the fluctuation in electrode dimension is large. However, as for the filament positioned apart from the electrode center, as shown in FIG. 8B, the parasitic resistance by the current flowing in an electrode end closer to the filament is dominant. Since a current component flowing in the electrode end apart from the filament is originally small, the fluctuation in parasitic resistance due to the fluctuation in electrode dimension is not large. Therefore, the fluctuation in parasitic resistance due to the fluctuation in electrode dimension can be prevented by applying the relational expression derived with respect to the filament positioned in the vicinity of center of the electrode.

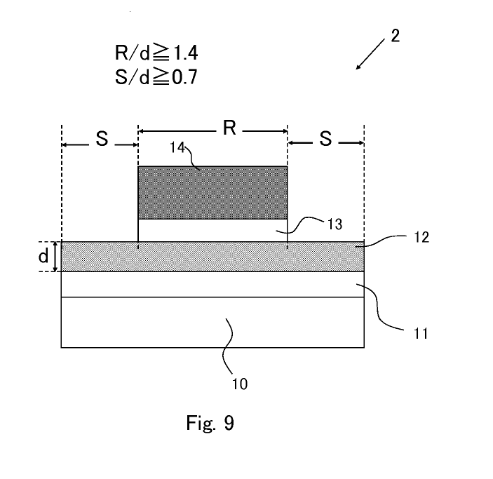

However, as shown in a variable resistive element 2 in FIG. 9 (hereinafter, referred to as the present element 2 occasionally), when the second electrode (specific electrode) 12 extends outward from the boundary of the contact region with the variable resistor 13 by a distance S, and the distance S is set to be more than 0.7 time as long as the film thickness d of the specific electrode (S/d≧0.7), the fluctuation in parasitic resistance due to the fluctuation in electrode dimension can be more surely prevented because a distance r from a filament formed at the end of the contact region to the boundary of the specific electrode becomes 0.7 or more.

In addition, the present element 1 preferably satisfies the above condition with respect to each of the first electrode 14 and the second electrode 12. However, the parasitic resistance is dominant in the electrode having the higher resistivity, so that the above condition is to be satisfied in at least the electrode having the higher resistivity (specific electrode) of the first electrode 14 and the second electrode 12. For example, in the case of the variable resistive element having the Ta/HfO_{X}/TiN structure, the above condition is to be satisfied in the TiN electrode having the higher resistivity.

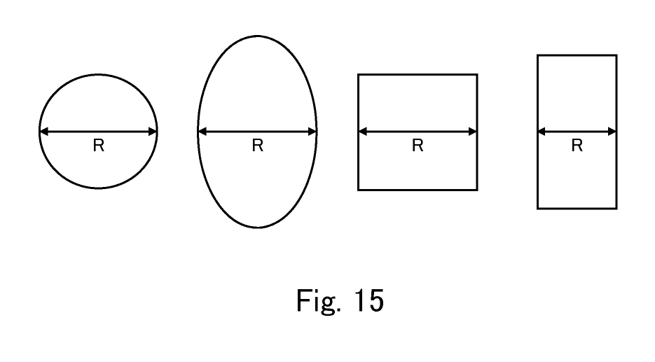

In addition, the above relational expression R/d≧1.4 is derived based on the calculation result of the disk-shaped electrode, but it can be applied to a specific electrode having a shape other than the disk shape. In a case of an oval shape, a short axis length is regarded as R, in a case of a roughly square shape, one side length is regarded as R, and in a case of a roughly rectangular shape, a length of a short side is regarded as R, as shown in FIG. 15, and the condition R/d≧1.4 is to be satisfied. In this case, the variation in parasitic resistance due to the variation in process dimension can be reduced similarly to or more than the disk-shape electrode.

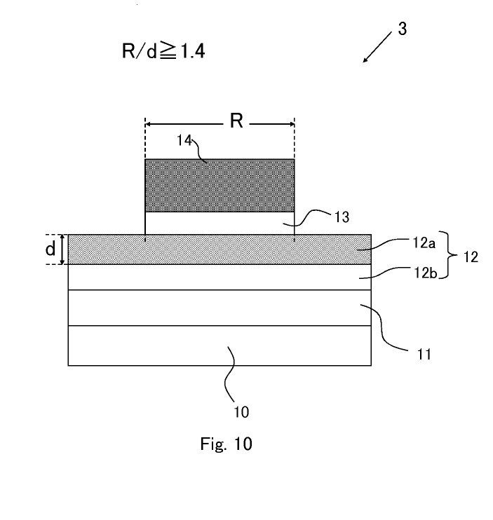

In addition, as shown in a variable resistive element 3 in FIG. 10 (hereinafter, referred to as the present element 3 occasionally), in a case where the second electrode 12 has a laminated structure of an electrode 12a and an electrode 12b, at least the electrode 12a which is in contact with the variable resistor is to satisfy the above relational expression. For example, in order to reduce variation in filament formed by the forming process among the elements, a buffer layer is sometimes inserted between the variable resistor and the electrode to prevent the current flowing between the electrodes of the variable resistive element from being abruptly increased at the time of the completion of the forming process. In this case, since the electrode is configured by the laminated structure of the buffer layer formed of oxide and a metal material layer, the buffer layer is to be regarded as the specific electrode which is in contact with the variable resistor and configured so as to satisfy the above relational expression.

### Second Embodiment

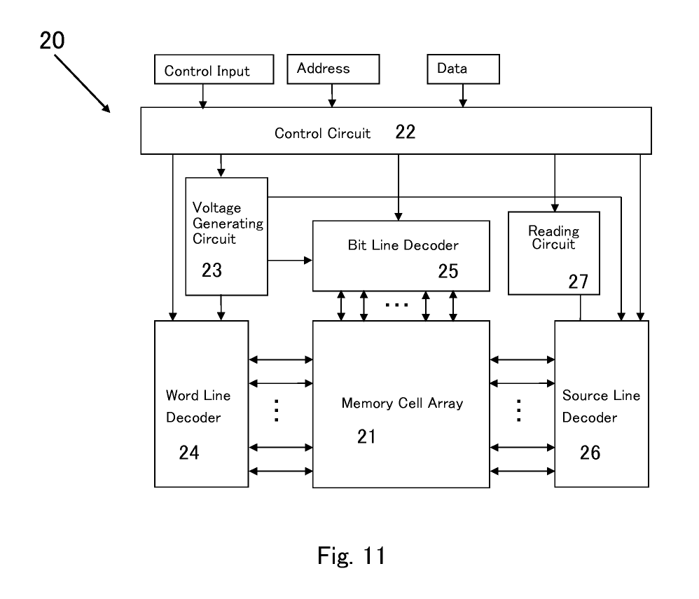

FIG. 11 illustrates a non-volatile semiconductor memory device using the present elements 1 to 3 described above. FIG. 11 is a circuit block diagram illustrating a schematic configuration of a non-volatile semiconductor memory device 20 (hereinafter referred to as a “present device 20” as needed) according to one embodiment of the present invention. As illustrated in FIG. 11, the present device 20 includes a memory cell array 21, a control circuit 22, a voltage generating circuit 23, a word line decoder 24, a bit line decoder 25, a source line decoder 26, and a read circuit 27.

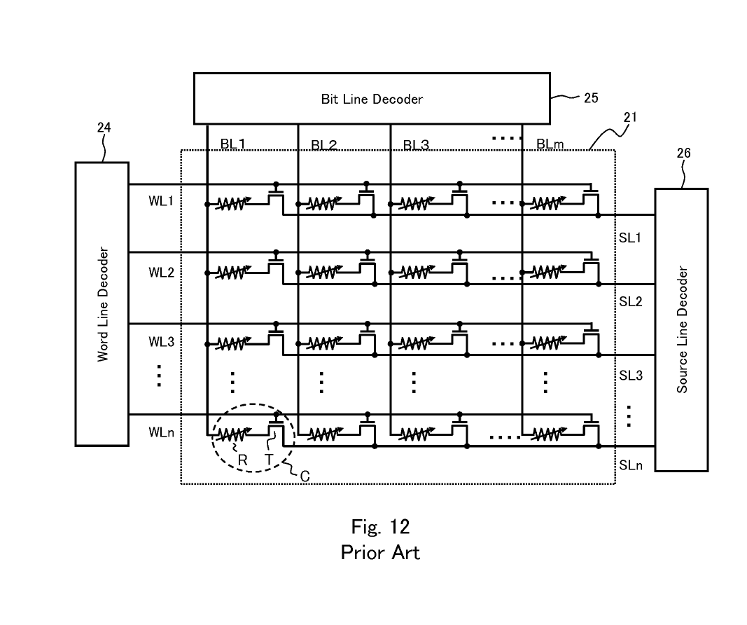

The memory cell array 21 includes a plurality of memory cells, each of which includes any one of the present elements 1 to 3 as a memory element, arranged in at least one of a row direction and a column direction in a matrix. The memory cells belonging to the same column are connected by a bit line extending in the column direction, and the memory cells belonging to the same row are connected by a word line extending in the row direction. The memory cell array 21 is the one illustrated in an equivalent circuit diagram in FIG. 12, for example. In addition, the variable resistive element R shown in FIG. 12 is composed of any one of the present elements 1 to 3.

As shown in FIG. 12, the memory cell array 21 is a 1T1R memory cell array in which a unit memory cell includes a transistor T serving as a current limiting element. One electrode of the variable resistive element R is connected to one of a source or a drain of the transistor T in series to form a memory cell C. The other electrode, not connected to the transistor T, of the variable resistive element R is connected to bit lines BL1 to BLm (m is a natural number) extending in the column direction (in the vertical direction in FIG. 12), the other one of the source and the drain of the transistor T that is not connected to the variable resistive element R is connected to source lines SL1 to SLn (n is a natural number) extending in the row direction (in the lateral direction in FIG. 12), and the gate terminals of the transistors are connected to word lines WL1 to WLn extending in the row direction. Any one of selected word line voltage and non-selected word line voltage is applied through the word line, any one of selected bit line voltage and non-selected bit line voltage is applied through the bit line, and any one of selected source line voltage and non-selected source line voltage is applied through the source line, wherein these voltages are independently applied. With this process, one or a plurality of memory cells, which are targets of the action and designated by an address input from the outside in each action such as a programming action, erasing action, reading action, and forming process, can be selected.

The control circuit 22 controls each of the memory actions such as the programming action (an action for decreasing the resistance: set operation), the erasing action (an action for increasing the resistance: reset operation), and reading action of the memory cell array 21, and controls the forming process. Specifically, the control circuit 22 controls the word line decoder 24, the bit line decoder 25, and the source line decoder 26 based upon an address signal inputted from an address line, a data input inputted from the data line, and a control input signal inputted from an a control signal line, thereby controlling each memory action in each memory cell and the forming process. In an example shown in FIG. 12, the control circuit 22 has a function of a general address buffer circuit, a data input/output buffer circuit, and a control input buffer circuit although not illustrated.

The voltage generating circuit 23 generates the selected word line voltage and non-selected word line voltage necessary for selecting the target memory cell during each of the programming action (an action for decreasing the resistance: set operation), the erasing action (an action for increasing the resistance: reset operation), and the reading action of the memory, and the forming process of the memory cell, and supplies the resultant to the word line decoder 24. The voltage generating circuit 23 also generates the selected bit line voltage and non-selected bit line voltage, and supplies the resultant to the bit line decoder 25. The voltage generating circuit 23 also generates the selected source line voltage and non-selected source line voltage, and supplies the resultant to the source line decoder 26.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the word line decoder 24 selects the word line corresponding to the address signal inputted to the address line, and applies the selected word line voltage and the non-selected word line voltage to the selected word line and to the non-selected word line, respectively.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the bit line decoder 25 selects the bit line corresponding to the address signal inputted to the address line, and applies the selected bit line voltage and the non-selected bit line voltage to the selected bit line and to the non-selected bit line, respectively.

When the target memory cell is inputted to the address line to be designated during each of the programming action (an action for decreasing the resistance: set operation), the erasing action (an action for increasing the resistance: reset operation), and the reading action of the memory, and the forming process of the memory cell, the source line decoder 26 selects the source line corresponding to the address signal inputted to the address line, and applies the selected source line voltage and the non-selected source line voltage to the selected source line and to the non-selected source line, respectively.

The reading circuit 27 detects the current flowing in the variable resistive element of the memory cell selected by application of a reading voltage at the time of the reading action, and determines whether the variable resistive element of the selected memory cell is in the high resistance state or the low resistance state.

Therefore, the control circuit 22, the voltage generating circuit 23, the word line decoder 24, the bit line decoder 25, and the source line decoder 26 shown in FIG. 12 serve as information writing circuits as a whole to program or erase information by applying a writing voltage to both ends of the selected memory cell and changing the electric resistance between the electrodes of the variable resistive element. The control circuit 22, the voltage generating circuit 23, the word line decoder 24, the bit line decoder 25, the source line decoder 26, and the reading circuit 27 shown in FIG. 12 serve as information reading circuits as a whole to read stored information by applying the reading voltage to both ends of the selected memory cell and detecting the electric resistance between the electrodes of the selected variable resistive element, based on the current amount flowing in the variable resistive element.

The detailed circuit structure of the control circuit 22, the voltage generating circuit 23, the word line decoder 24, the bit line decoder 25, the source line decoder 26, and the reading circuit 27 can be realized by using a known circuit structure, and the device structure of these components can be manufactured by using a known semiconductor manufacturing technique. Therefore, the detailed circuit structure, the device structure, and the manufacturing method will not be described here.

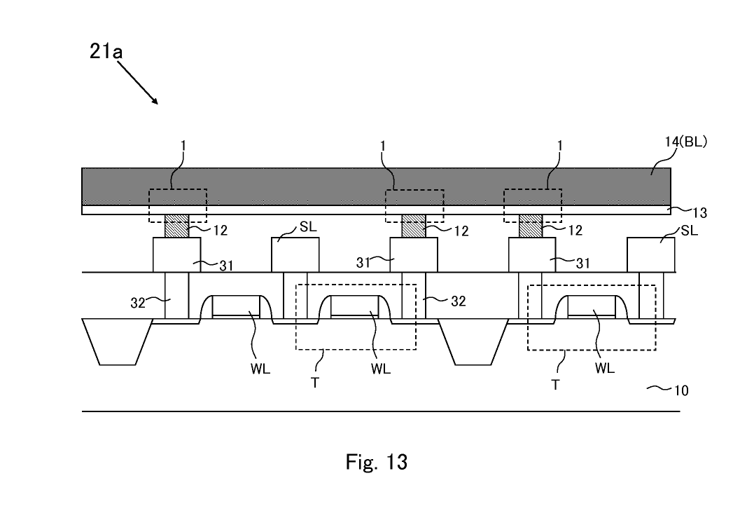

FIG. 13 is a sectional view schematically illustrating one example of a structure of the memory cell array 21 including the present element 1 in a memory cell. The memory cell array 21a whose cross-section is illustrated in FIG. 13 is the 1T1R memory cell array. In the memory cell array 21a, the first electrode 14 extends in the column direction (in the lateral direction in FIG. 13) to form the bit line BL, and the variable resistor 13 similarly extends in the column direction. The contact plug that connects the transistor T formed in the lower layer via the island-like metal wiring 31 and contact plug 32 is the second electrode 12 which is in contact with the variable resistor 13. The variable resistive element 1 including the first electrode 14, the variable resistor 13, and the second electrode 12 is formed on the contact region (element formation region) where the second electrode 12 is in contact with the variable resistor 13.

In the case where the second electrode 12 is formed of TiN as the specific electrode having high resistivity, the variable resistor 13 is formed of hafnium oxide HfO_{X}, and the first electrode 14 is formed of Ti or Ta, the variable resistive element is to be formed such that the dimension of the second electrode 12 (that is, the diameter R and the depth d of the contact plug filled with the second electrode 12) satisfies the relational expression R/d≧1.4. Thus, it becomes possible to reduce the effect due to the variation in parasitic resistance caused by the process variation of the second electrode 12, so that the variation in switching characteristics is prevented and an operation margin is large in a highly integrated memory.

Thus, according to the present invention, as for the filament type variable resistive element, by satisfying the above relational expression regarding the electrode dimension R and the film thickness d of the specific electrode having high resistivity, the problem caused by the parasitic resistance of the variable resistive element and the variation in parasitic resistance can be solved, and by employing this variable resistive element for the memory element in the memory cell, the variation in switching characteristics is prevented and the operation margin is large in the highly integrated memory.

### Other Embodiments

Hereinafter, other embodiments will be described.

(1) In the above embodiment, the description has been given of the case where the resistivity of the electrode of each of the present elements 1 to 3 is relatively high and especially the resistivity of the specific electrode is 100 μΩcm or more. However, as long as the filament type variable resistive element satisfies the relational expression R/d≧1.4 as the relationship between the electrode dimension R and the film thickness d of the electrode, it is apparent that the variable resistive element attains the effect of the present invention in which the parasitic resistance in the electrode part can be reduced, and the variation in parasitic resistance can be reduced. However, it is to be noted that the present invention is especially suitable for the case where the resistivity of the electrode is 100 μΩcm or more.

(2) Although the variable resistive elements having the element structures illustrated in FIGS. 1, 9 and 10 are described as examples in the first embodiment described above, the present invention is not limited to the element having such a structure. As long as the electrode dimension R and the film thickness d of the specific electrode satisfy the above relational expression, the present invention can be applied to the variable resistive element having any structure.

(3) In the second embodiment, the present device 20 is applicable to any memory cell array including a plurality of memory cells arranged in a matrix, so long as the variable resistive element according to the present invention is used in each of the memory cells. The present invention is not limited by the structure of the memory cell array 21 or the circuit structure of the other circuits such as the control circuit or the decoders. In particular, the memory cell array 21 may be a 1R memory cell array that does not contain a current limiting element in a unit memory cell, or may be a 1D1R memory cell array including a diode, serving as a current limiting element, in a unit memory cell, in addition to the 1T1R memory cell array 21 illustrated in FIG. 12. In the 1D1R memory cell array, one end of the diode and one electrode of the variable resistive element are connected in series to form a memory cell, any one of the other end of the diode and the other electrode of the variable resistive element is connected to the bit line extending in the column direction, and the other one is connected to the word line extending in the row direction. In the 1R memory cell array, both electrodes of the variable resistive element are respectively connected to the bit line extending in the column direction and to the word line extending in the row direction.

(4) The present device 20 includes the source line decoder 26 for selecting the source lines SL1 to SLn, wherein each source line is selected to allow the voltage necessary for the operation of the memory cell to be applied. However, the source line may be shared by all memory cells, and a ground voltage (fixed potential) may be supplied to the source line. Even in this case, the voltage necessary for the operation of the memory cell can be supplied by selecting each of bit lines BL1 to BLn through the bit line decoder 25.

The present invention is applicable to a non-volatile semiconductor memory device, and more particularly applicable to a non-volatile semiconductor memory device including a non-volatile variable resistive element whose resistance state is changed due to application of voltage, the resistance state after the change being retained in a non-volatile manner.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A variable resistive element comprising a first electrode, a second electrode, and a variable resistor containing a metal oxide, the variable resistor being provided between the first and second electrodes, wherein
electric resistance between the first and second electrodes is reversibly changed in response to application of an electric stress to between the first and second electrodes,
the metal oxide includes a current path where a current density of a current flowing between the first and second electrodes is locally high,
resistivity of at least one specific electrode having higher resistivity of the first electrode and the second electrode is 100 μΩcm or more, and
a dimension of a contact region of the specific electrode with the variable resistor in a short side direction or a short axis direction is more than 1.4 times as long as a film thickness of the specific electrode.

2. The variable resistive element according to claim 1, wherein
the specific electrode is formed to have a dimension larger than the variable resistor in the short side direction or the short axis direction, and
the specific electrode extends from a boundary of the contact region to an outer region by more than 0.7 times as long as the film thickness of the specific electrode.

3. The variable resistive element according to claim 1, wherein
the specific electrode is formed of a material containing nitrogen, an oxide material, or a silicon material doped with an impurity.

4. The variable resistive element according to claim 1, wherein
the dimension of the contact region in the short side direction or the short axis direction is 50 nm or less.

5. A semiconductor device comprising:
a semiconductor substrate; and
a plurality of memory cells over the semiconductor substrate, each of the memory cells including a variable resistive element that includes:
a first conductive layer;
a second conductive layer greater in resistivity than the first conductive layer, a resistivity of the second conductive layer being equal to or more than 100 μΩcm, and a thickness of the second conductive layer is a first value; and
a variable resistive film sandwiched between the first and second conductive layer to define a contact region between the variable resistive film and the second conductive layer, a shape of the contact region being substantially a circle shape of which diameter is equal to or more than 1.4 times as the first value.

6. The semiconductor device according to claim 5, wherein the second conductive layer includes a first surface, the variable resistive film including a second surface connecting to the first surface to define the contact region, the first surface being larger than the second surface.

7. The semiconductor device according to claim 6, wherein the second conductive layer is formed of at least one of a material containing nitrogen, an oxide material, and a silicon material doped with an impurity.

8. The semiconductor device according to claim 6, wherein the diameter of the circle shape of the contact region is equal to or less than 50 nm.

9. A semiconductor device comprising:
a semiconductor substrate; and
a plurality of memory cells over the semiconductor substrate, each of the memory cells including a variable resistive element that includes:
a first conductive layer;
a second conductive layer greater in resistivity than the first conductive layer, a resistivity of the second conductive layer being equal to or more than 100 μΩcm, and a thickness of the second conductive layer is a first value; and
a variable resistive film sandwiched between the first and second conductive layer to define a contact region between the variable resistive film and the second conductive layer, a shape of the contact region being substantially an ellipse shape of which a minor axis is equal to or more than 1.4 times as the first value.

10. The semiconductor device according to claim 9, wherein the second conductive layer includes a first surface, the variable resistive film including a second surface connecting to the first surface to define the contact region, the first surface being larger than the second surface.

11. The semiconductor device according to claim 10, wherein the second conductive layer is formed of at least one of a material containing nitrogen, an oxide material, and a silicon material doped with an impurity.

12. The semiconductor device according to claim 10, wherein the diameter of the circle shape of the contact region is equal to or less than 50 nm.
